(19) United States
(12) Patent Application Publication
(10) Pub. No.: US 2006/0196605 A1
(43) Pub. Date: Sep. 7, 2006

(54) Method and apparatus for plasma processing

(76) Inventors: Eiji Ikegami, Kudamatsu-shi (JP); Kunihiko Koroyasu, Kudamatsu-shi (JP); Tadamitsu Kanekiyo, Kudamatsu-shi (JP); Masahiro Sumiya, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/190,839

(22) Filed: Jul. 28, 2005

(30) Foreign Application Priority Data
Mar. 7, 2005 (JP) 2005-062842

(51) Int. Cl. H01L 21/306; C23F 1/00; C23C 16/00; H05H 1/24

(52) U.S. Cl. 156/345.51; 427/248.1; 427/569; 118/728; 216/67

(57) ABSTRACT

In processing a semiconductor device, foreign particles that may cause defects are reduced to improve production yield without decreasing availability of a semiconductor manufacturing apparatus. The apparatus comprises a mechanism operable to control an ion sheath 32w on an electrode 14 for mounting a wafer 2 and an ion sheath 32f on a member 141 mounted on the periphery of the electrode 14. The thickness of the ion sheath 32f is made smaller than the thickness of the ion sheath 32w to provide a slope of ion sheath 32s near the edge of the wafer 2, thereby causing ions 31 to be obliquely incident on the wafer edge to reduce deposition film on the wafer edge.

The present application is based on and claims priority of Japanese patent applications No. 2005-062842 filed on Mar. 7, 2005, the entire contents of which are hereby incorporated by reference.

### BACKGROUND OF THE INVENTION

1. Field of the Invention

This invention relates to a plasma processing method and apparatus for use in processing a semiconductor integrated device, and more particularly to a plasma etching method and apparatus.

2. Description of the Related Art

In recent years, there is an increasing demand for enhanced capabilities on semiconductor devices, where elements tend to be integrated at high density. This requires processing with finer design rules. In view of this background, plasma etching processes tend to often use highly depositing gas for ensuring high processing accuracy. Highly depositing gas forms film on the surface of process chamber components adjacent to plasma other than on the wafer surface. Part of the film is deposited on the bevel (wafer edge) and wafer rear face by sputtering or the like. During processing, part of the deposits (deposition film) may peel off, float in the air, and fall on the wafer, which disturbs processing and leads to failure to achieve a desired processing result. In addition, deposition on the bevel (bevel deposition) produced during the plasma etching process may become a source of foreign particles for subsequent processes.

To solve this problem, a method of manufacturing a semiconductor device has been proposed in which an exchangeable member for forming deposition film is placed on the periphery of the wafer mounting electrode to reduce deposition formation on the side face of the wafer mounting electrode (see, e.g., Japanese Laid-Open Patent Application 2001-230234).

In a proposal presented in Japanese Patent Application 2004-264168, bias power applied to a ring mounted around the wafer periphery is adjusted during the process time so that foreign particles staying in the space above the wafer are guided toward and fall onto the ring, thereby providing for reduction of foreign particles.

However, the conventional technology has a problem that repetition of plasma etching causes reaction products and the like to attach on the lower face of the wafer periphery (bevel), which forms thick deposition film.

### SUMMARY OF THE INVENTION

In view of the above problems, an object of the invention is to provide a plasma processing apparatus and method for manufacturing a semiconductor integrated device, the apparatus and method being capable of reducing generation of deposits (deposition film) on a wafer edge (bevel).

To solve the above problems, the invention provides a mechanism operable to control the ion sheaths on the electrode for mounting a wafer and on the member mounted on the periphery of the electrode, thereby causing ions to be obliquely incident on the wafer edge to reduce deposition on the rear face of the wafer edge.

According to the invention, in manufacturing a semiconductor integrated device, generation of bevel deposition can be prevented to improve production yield.

### BRIEF DESCRIPTION OF THE DRAWINGS

FIG. 1 is a schematic cross-sectional view of a UHF plasma etching apparatus illustrating a first embodiment of the invention.

FIG. 2 is a principle diagram illustrating the principle of reducing bevel deposition film.

FIG. 3 is a diagram illustrating the effect of reducing bevel deposition film during an etching process.

FIG. 4 is a principle diagram illustrating the principle of reducing deposition film on the wafer periphery.

FIG. 5 is a diagram illustrating the effect of removing bevel deposition film during an ashing process.

FIG. 6 is a schematic cross-sectional view illustrating the structure of a lower electrode of an etching apparatus according to a second embodiment of the invention.

FIG. 7 is a schematic cross-sectional view illustrating the structure of a lower electrode of an etching apparatus having an elevator for height control according to a third embodiment of the invention.

FIG. 8 is a schematic cross-sectional view illustrating the structure of a lower electrode of an etching apparatus where the member mounted around the wafer periphery is a stacked body according to a fourth embodiment of the invention.

FIG. 9 is a schematic cross-sectional view illustrating the structure of a lower electrode of an etching apparatus where the member mounted around the wafer periphery is an insulator ring according to a fifth embodiment of the invention.

### DETAILED DESCRIPTION OF THE PREFERRED EMBODIMENTS

### First Embodiment

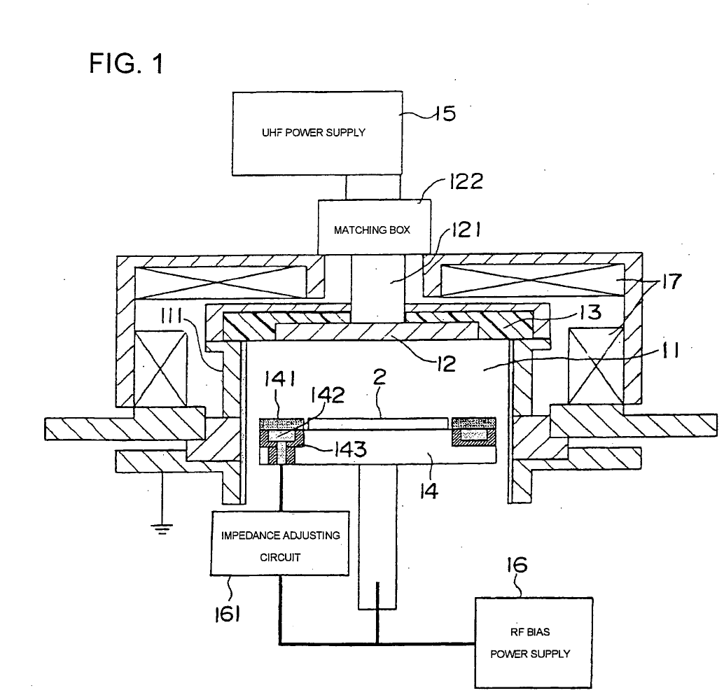

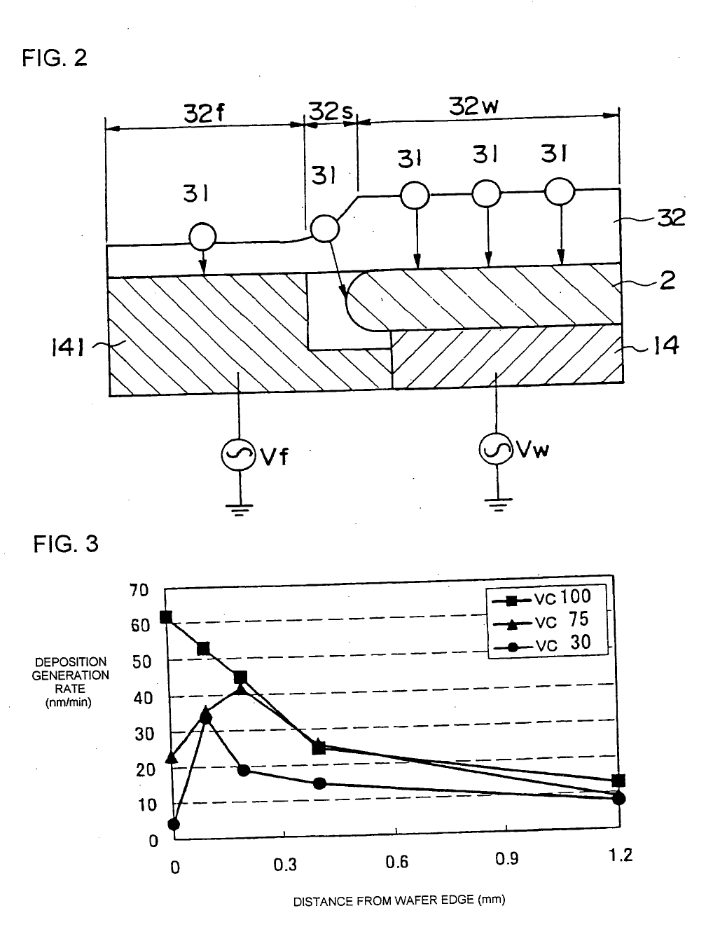

The first embodiment of the invention will now be described with reference to FIGS. 1 and 2. FIG. 1 shows a plasma etching apparatus that uses UHF-ECR (Electron Cyclotron Resonance) to which the invention is applied. As shown, in this UHF-ECR plasma etching apparatus, UHF electromagnetic waves are emitted from an antenna 12 and generate plasma by interaction with magnetic field.

The plasma etching apparatus 1 comprises an etching (plasma) chamber 11, an antenna 12 placed above the etching chamber 11, a dielectric 13, a lower electrode 14 opposed to the antenna 12, a UHF power supply 15 for supplying the antenna 12 with RF power for generating plasma, an RF bias power supply 16 for supplying the lower electrode 14 with bias power, and a magnetic field coil 17 for generating plasma in the plasma chamber (etching chamber) 11. The antenna 12 is supplied with RF power for plasma generation from the UHF power supply 15 via a waveguide 121 and a matching box 122. The lower electrode 14 is supplied with bias power from the RF bias power supply 16. In this invention, a silicon ring 141 serving as a focus ring, a conductor ring 142, and an insulator ring 143 are provided on a periphery portion of the lower electrode 14 not covered with a mounted wafer 2, and are supplied with RF power from the RF bias power supply 16 via an impedance adjusting circuit 161.

In this embodiment, the temperature of the inner wall 111 of the etching chamber 11 can be adjusted in a temperature range of 20 to 100° C. by a temperature adjusting means (not shown) The antenna 12 is placed above the etching chamber 11. The dielectric 13, which can transmit UHF electromagnetic waves, is placed between the etching chamber 11 and the antenna 12. The antenna 12 herein is connected to the UHF power supply 15 for generating UHF electromagnetic waves via the waveguide 121 and the matching box 122. The magnetic field coil 17 for generating magnetic field in the etching chamber 11 is wound around the periphery of the etching chamber 11. The lower electrode 14 serving as a sample stage for mounting the wafer 2 is provided below the antenna 12 in the etching chamber 11. The silicon ring 141 is placed via the insulator ring 143 and the conductor ring 142 on the portion of the lower electrode 14 not covered with the mounted wafer. The conductor ring 142 is connected to the RF bias power supply 16 via the impedance adjusting circuit 161 external to the etching chamber 11.

In the plasma processing apparatus as configured above, UHF electromagnetic waves outputted from the UHF power supply 15 are carried via the matching box 122, waveguide 121, and dielectric 13 to the antenna 12, from which they are supplied to the etching chamber 11. On the other hand, a magnetic field is produced in the etching chamber 11 by the magnetic field coil 17 around the etching chamber 11. Etching gas introduced into the etching chamber 11 is efficiently turned into plasma by interaction between the electric field of the UHF electromagnetic waves and the magnetic field of the magnetic field coil. In such a plasma process, bevel deposition is reduced by adjusting the bias voltage outputted from the RF bias power supply 16 using the impedance adjusting circuit 161 so that the voltage applied to the silicon ring 141 is smaller than the voltage applied to the wafer 2.

The principle of reducing bevel deposition is described with reference to FIG. 2. For example, UHF electromagnetic waves at 200 MHz are applied from the UHF power supply 15 to the antenna 12. Ar, CHF₃, and N₂ are used for plasma gas. The processing pressure is controlled at 4 Pa. RF bias voltage at 4 MHz is applied from the RF bias power supply 16 to the lower electrode 14. The impedance adjusting circuit 161, which is composed of a variable capacitor, for example, is used to adjust the voltage Vf applied to the silicon ring (focus ring) 141 mounted on the periphery of the electrode to be smaller than the voltage Vw applied to the electrode portion where the wafer 2 is mounted (e.g., 500 V as compared to 1500 V).

This causes the ion sheath 32f on the focus ring 141 to be thinner than the ion sheath 32w on the wafer 2. In this way, a slope of ion sheath 32s descending from the ion sheath 32w to the ion sheath 32f is formed in the ion sheath 32 near the periphery of the wafer 2.

As a result, the bias voltage applied to the electrode 14 causes ions 31 located above the wafer 2 and the focus ring 141 to be vertically incident on the wafer 2 and the focus ring 141, respectively. On the other hand, ions 31 located in the ion sheath 32s on the periphery of the wafer 2 are obliquely incident on the side face of the wafer 2. The ions 31 obliquely incident on the side face of the wafer 2 reduces generation of deposition film formed on the rear face of the bevel (periphery) of the wafer 2.

Advantageous effects of the invention are described with reference to FIG. 3. “VC 100” refers to a case where the voltage Vf applied to the focus ring 141 is equal to the voltage Vw applied to the wafer 2 (Vw:Vf=100:100). “VC 75” refers to a case where the voltage Vf applied to the focus ring 141 is smaller than the voltage Vw applied to the wafer 2 (Vw:Vf=100:75). “VC 30” refers to another case where the voltage Vf applied to the focus ring 141 is smaller than the voltage Vw applied to the wafer 2 (Vw:Vf=100:30). The rate of deposition film generation on the rear face of the bevel (periphery) of the wafer 2 is decreased by selecting the relation between the voltage Vw applied to the wafer 2 and the voltage Vf applied to the focus ring 141 as Vw>Vf, that is, by selecting the cases of VC 75 or VC 30, as compared to VC 100. This shows that bevel deposition can be reduced by selecting the voltage Vf applied to the focus ring 141 to be smaller than the voltage Vw applied to the wafer 2.

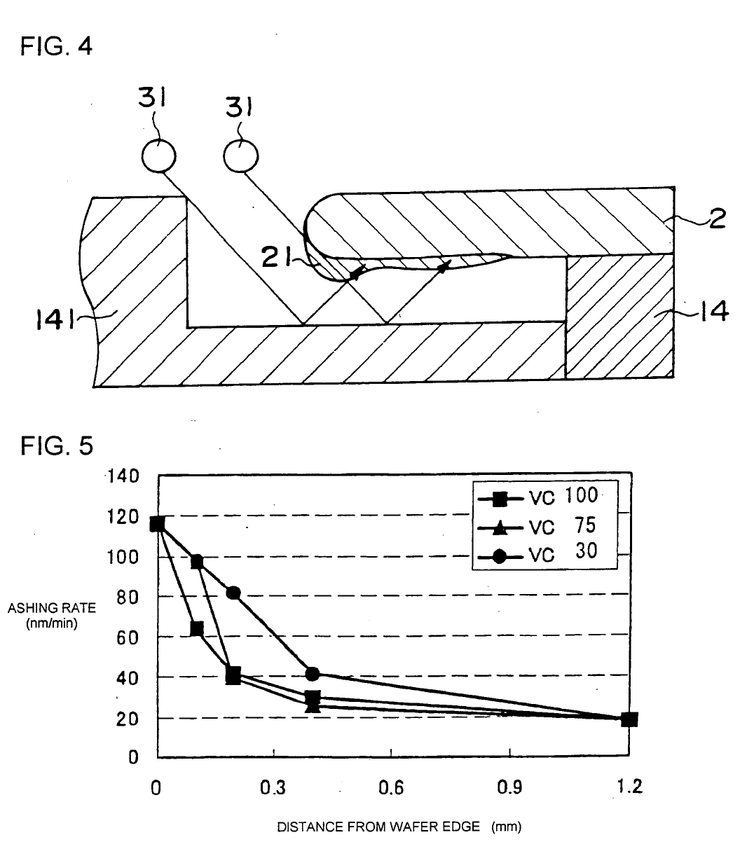

It is noted that in VC 75 and VC 30, the rate of deposition film generation is partly increased between the wafer outermost periphery (0 mm) and 0.3 mm. As shown in FIG. 4, this is presumably because obliquely incident ions 31 are reflected by the silicon ring 141 and do not contribute to reduction of deposition film 21 between the outermost periphery (0 mm) and 0.3 mm of the wafer 2, or because deposition with high attachment coefficient is easy to attach to the wafer edge having a large angle of attack. However, the deposition film 21 between the wafer outermost periphery (0 mm) and 0.3 mm can also be reduced by controlling the thickness of the sheath 32.

The plasma generating RF power supply (UHF power supply) 15 described above is not limited to that of 200 MHz, but is also applicable in the range of 10 MHz to 2.5 GHz. The frequency of 10 MHz is the frequency for obtaining the minimum required plasma density. The frequency of 2.5 GHz is the limit to achieve uniformity of a large diameter. Similarly, the RF power supply (RF bias power supply) 16 for attracting ions 31 is not limited to an RF power of 4 MHz, but is also applicable in the range of 400 kHz to 200 MHz. The frequency of 400 kHz is the minimum frequency to avoid manifest wafer damage. At frequencies exceeding 200 MHz, self-bias is not generated. The processing pressure is not limited to 4 Pa, but a similar effect of the invention is also achieved at pressures in the range of 0.1 to 100 Pa. The pressure of 0.1 Pa is the threshold to produce etchant and ions required for etching. The pressure of 100 Pa is the limit below which ions are not scattered from each other and ions 31 can be controlled by the ion sheath 32.

The above embodiment has been described with reference to a UHF-ECR etching apparatus. However, the invention is not limited to the above embodiment, but is applicable to CCP (Capacitively Coupled Plasma), ICP (Inductively Coupled Plasma), SWP (Surface Wave Plasma), HEP (Helico-Wave Excited Plasma), TCP (Transfer Coupled Plasma), and other etching apparatuses.

FIG. 5 shows a result of applying the invention to a plasma process for stripping a resist mask (ashing) using the above UHF-ECR etching apparatus and plasma gas of O₂. The rate of ashing is faster in VC 30 than in VC 100. This is presumably because the voltage Vf applied to the silicon ring 141 is made smaller than the voltage Vw applied to the wafer 2 using the impedance adjusting circuit 161 to cause ions to be incident obliquely and reach the rear face of the wafer periphery, thereby accelerating the rate of removing deposition film by the ion assist effect on the reaction of O radicals. The gas species is not limited to O₂, but the invention is also applicable to H₂, or gas containing O or H.

The embodiment of a plasma process for resist stripping (ashing) has been described with reference to a UHF-ECR etching apparatus. However, the invention is not limited to the above embodiments, but is applicable to CCP, ICP, SWP, HEP, TCP, and other etching apparatuses.

### Second Embodiment

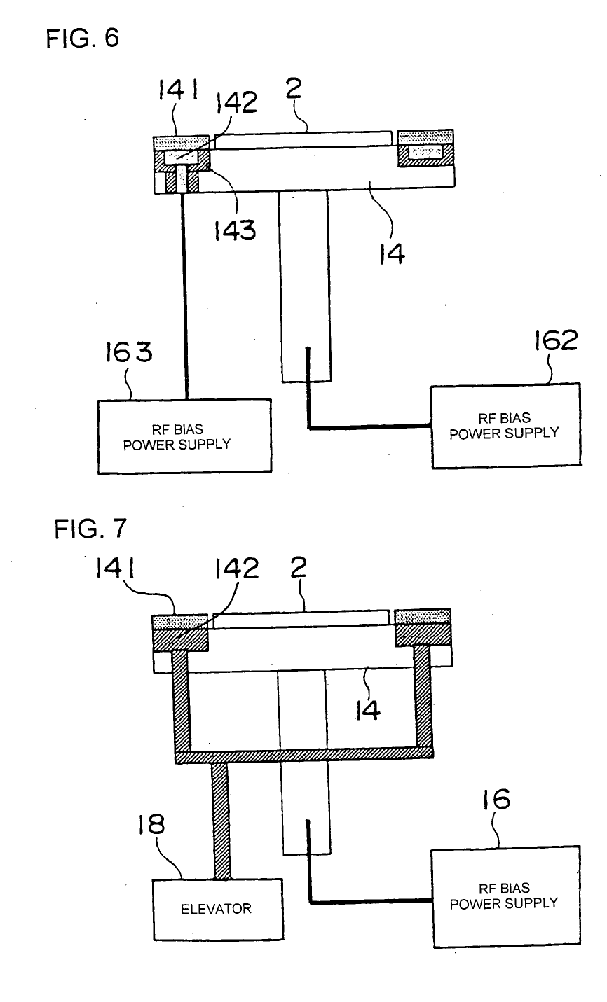

The second embodiment of the invention is described with reference to FIG. 6. In the second embodiment, a first RF bias power supply 162 for applying RF bias to the lower electrode 14 and a second RF bias power supply 163 for applying RF bias to the silicon ring 121 are provided as separate power supplies. The power of the second RF bias power supply 163 is set to be smaller than the power of the first RF bias power supply 162, and thereby the thickness of the ion sheath on the silicon ring 141 is made smaller than the thickness of the ion sheath on the wafer 2 to form a slope of the ion sheath. In this way, ions are caused to be obliquely incident on the bevel to reduce bevel deposition film.

### Third Embodiment

The third embodiment of the invention is described with reference to FIG. 7. In the third embodiment, the height of the silicon ring 141 is made lower than the height of the wafer 2 using the elevator 18, and thereby the ion sheath 32f on the silicon ring 141 is made lower than the ion sheath 32w on the wafer 2 to form a slope of the ion sheath 32. In this way, ions are caused to be obliquely incident on the bevel to reduce bevel deposition film.

### Fourth Embodiment

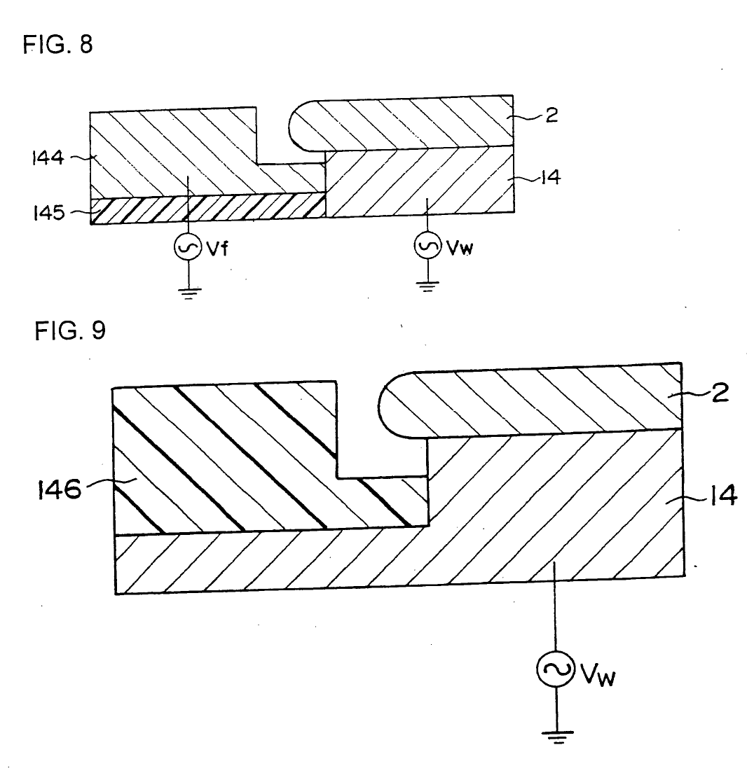

The fourth embodiment of the invention is described with reference to FIG. 8. In the fourth embodiment, a stacked body of silicon 144 and insulator 145 is substituted for the silicon ring 141 in the first embodiment, and thereby the thickness of the ion sheath on the silicon ring 141 is made smaller than the thickness of the ion sheath on the wafer 2 to form a slope of the ion sheath. In this way, ions are caused to be obliquely incident on the bevel to reduce bevel deposition film.

### Fifth Embodiment

The fifth embodiment of the invention is described with reference to FIG. 9. In the fifth embodiment, an insulator ring 146 is substituted for the silicon ring 141 in the first embodiment, and thereby the thickness of the ion sheath on the silicon ring 141 is made smaller than the thickness of the ion sheath on the wafer 2 to form a slope of the ion sheath. In this way, ions are caused to be obliquely incident on the bevel to reduce bevel deposition film.

What is claimed is:

1. A plasma processing method comprising:
using a plasma processing apparatus having a mechanism operable to control sheaths on an electrode for mounting a wafer and on a member mounted on a periphery of the electrode to cause ions to be obliquely incident on an edge of the wafer to reduce deposition on the edge of the wafer.

2. A plasma processing apparatus for generating plasma to process a wafer, the apparatus comprising:
an electrode for mounting the wafer;
a member provided on a periphery of the electrode; and
at least one RF bias power supply for applying RF bias voltage to the electrode and to the member provided on the periphery of the electrode, wherein
a ratio between the RF bias voltage applied to the electrode and the RF bias voltage applied to the member provided on the periphery of the electrode is adjusted.

3. A plasma processing apparatus according to claim 2, wherein an impedance adjusting circuit for dividing the RF bias voltage applied to the member provided on the periphery of the electrode is used as a mechanism for adjusting the ratio between the RF bias voltages.

4. A plasma processing apparatus according to claim 2, wherein an impedance adjusting circuit using a variable capacitor for dividing the RF bias voltage applied to the member provided on the periphery of the electrode is used as a mechanism for adjusting the ratio between the RF bias voltages.

5. A plasma processing apparatus according to claim 2, wherein two RF bias power supplies are used as a mechanism for adjusting the ratio between the RF bias voltages.

6. A plasma processing apparatus according to claim 2, wherein the member provided on the periphery of the electrode includes silicon.

7. A plasma processing apparatus according to claim 2, wherein the member provided on the periphery of the electrode includes a stacked body of silicon and insulator.

8. A plasma processing apparatus according to claim 2, wherein the member provided on the periphery of the electrode includes insulator.

9. A plasma processing apparatus according to claim 2, wherein a power supply for RF bias in a range of 400 kHz to 200 MHz is used as the RF bias power supply.

10. A plasma processing apparatus according to claim 2, wherein a power supply for RF in a range of 10 MHz to 2.5 GHz is used as a plasma generating RF power supply.

11. A plasma processing apparatus according to claim 2, wherein processing is performed at a plasma processing pressure in a pressure range of 0.1 to 100 Pa.

12. A plasma processing apparatus according to claim 2, wherein deposition film on a periphery of the wafer is removed during a plasma process for resist mask stripping.

13. A plasma processing apparatus according to claim 2, wherein deposition film on a periphery of the wafer is removed during a plasma process for resist mask stripping by using one or more of O₂, H₂, and gas containing one or more of O and H.

14. A plasma processing apparatus for generating plasma to process a wafer, the apparatus comprising:
an electrode for mounting the wafer;
a member provided on a periphery of the electrode; and
at least one RF bias power supply for applying RF bias voltage to the electrode and to the member provided on the periphery of the electrode, wherein
a mechanism operable to adjust the height of the member provided on the periphery of the electrode is provided as a mechanism for controlling the RF bias voltage applied to the electrode and an ion sheath on the member provided on the periphery of the electrode.
